(19) United States
(12) Patent Application Publication
(10) Pub. No.: US 2006/0105114 A1
(43) Pub. Date: May 18, 2006

(54) Multi-layer high quality gate dielectric for low-temperature poly-silicon TFTs

(76) Inventor: John M. White, Hayward, CA (US)

Correspondence Address: PATTERSON & SHERIDAN, LLP, 3040 POST OAK BOULEVARD, SUITE 1500, HOUSTON, TX, 77056, US

(21) Appl. No.: 10/990,185

(22) Filed: Nov. 16, 2004

(51) Int. Cl. C23C 16/00; H05H 1/24

(52) U.S. Cl. 427/569; 118/723 R

(57) ABSTRACT

A method and apparatus that is useful for forming a high quality gate dielectric layer in MOS TFT devices using a high density plasma oxidation (HDPO) process. The HDPO process forms a good interface and then a second layer, which has good bulk electrical properties, is deposited at a higher deposition rate over the HDPO layer. In one embodiment a thin HDPO process layer is formed over the channel, source and drain regions to form a high quality dielectric interface and then one or more dielectric layers are deposited on the HDPO layer to form a high quality gate dielectric layer. The HDPO process generally entails using an inductively and/or capacitively coupled RF energy transmitting device to generate and control the plasma generated over the surface of the substrate and injecting a gas containing an oxidizing source to grow the interfacial layer. A second dielectric layer may then be deposited on the surface of the substrate using a CVD or plasma enhanced CVD deposition process. Aspects of the present invention also provide a cluster tool that contains at least one specialized plasma processing chamber that is capable of depositing a high quality gate dielectric layer. The cluster tool is advantageous because it supports both the pre-processing steps, such as, preheating the substrate, pre-cleaning the surface of the substrate prior to processing, and cool down after processing, all in a single controlled environment.

### BACKGROUND OF THE INVENTION

1. Field of the Invention

Embodiments of the present invention generally relate to an apparatus and method used for fabricating electronic devices using a plasma processing system.

2. Description of the Related Art

In the fabrication of flat panel displays (FPD), thin film transistors (TFT) and liquid crystal cells, metal interconnects and other features are formed by depositing and removing multiple layers of conducting, semiconducting and dielectric materials on a glass substrate. The various features formed are integrated into a system that collectively is used to create, for example, active matrix display screens in which display states are electrically created in individual pixels on the FPD. Processing techniques used to create the FPD include plasma-enhanced chemical vapor deposition (PECVD), physical vapor deposition (PVD), etching, and the like. Plasma processing is particularly well suited for the production of flat panel displays because of the relatively lower processing temperatures required to deposit film and the good film quality which results.

A common FPD device utilized in the fabrication of TFT displays is a low temperature polysilicon (LTPS) TFT device as shown in prior art FIG. 1. LTPS TFT devices are MOS devices built with a source region 9A, channel region 9B, and drain region 9C formed on an optically transparent substrate 1. The source region 9A, channel region 9B, and drain region 9C are generally formed from an initially deposited amorphous silicon (a-Si) layer that is typically later annealed to from a polysilicon (p-Si) layer. The source, drain and channel regions can be formed by patterning areas on the optically transparent substrate 1 and ion doping the deposited initial a-Si layer, which is then annealed to form the polysilicon layer. A gate dielectric layer 4 is then deposited on top of the deposited p-Si layer(s) to isolate the gate 5 from the channel, source and drain regions. The gate 5 is formed on top of the gate dielectric layer 4. The gate dielectric layer 4 is also commonly known as a gate oxide layer since it is commonly made of a silicon dioxide (SiO₂) layer. An insulating layer 6 and device connections are then made through the insulating layer to allow control of the TFT devices.

The performance of a p-Si TFT device is dependent on the quality of the films that are deposited to form the MOS structure. The key performance elements of a MOS device are the qualities of the p-Si channel layer film, the gate dielectric layer film, and the p-Si/gate dielectric layer interface. The quality of the p-Si channel layer film has received a lot of attention in recent years, while the creation of a high quality gate dielectric layer and p-Si/gate dielectric interface has been elusive. The gate dielectric layer 4 is critical with respect to the electrical performance of the TFT device. In particular, the gate dielectric layer needs to be a high quality layer (e.g., a low flatband voltage (V_{fb})) in order to fabricate a transistor with desirable electrical performance, and a high breakdown voltage (V_{B}). The quality of the gate oxide will affect the device performance and thus the quality and usability of the FPD.

The gate dielectric layer 4 typically comprises an oxide, deposited using conventional techniques, such as, for example, PECVD, which is commonly deposited between about 350° C. and about 450° C. Unfortunately, the quality of the interface between the deposited film and the p-Si channel layer is often not satisfactory to meet the highest TFT device performance needs. The use of high temperature (e.g., >600° C.) deposition processes to form a good interface between the deposited film and the p-Si channel layer is often not possible because high deposition temperatures will promote inter-diffusion of the dopants in the layers already deposited, and also may not be compatible with the glass substrates upon which the thin film transistors are formed, since the glass may soften and become dimensionally unstable.

A robust LCD TFT gate dielectric film will have a high quality Si/SiO₂ interface characterized by a low interface-trapped charge, a low defect count in the dielectric layer, a low fixed oxide charge and a low mobile ion density, all formed at a processing temperature below 500° C.

Therefore, there is a need for a method and apparatus that can form a high quality gate dielectric layer for use in thin film transistors that overcome the above drawbacks.

### SUMMARY OF THE INVENTION

The present invention generally provides a plasma chamber for plasma processing a substrate, comprising one or more walls defining a plasma processing region, a substrate support member mounted in the plasma processing region and adapted to support a substrate at a plurality of vertically spaced apart positions, a RF transmitting device positioned to transmit RF energy to the plasma processing region, a RF power source connected to the RF transmitting device and an oxidizing gas source in communication with the plasma processing region.

The present invention generally provides a plasma chamber for plasma processing a substrate, comprising one or more walls defining a plasma processing region, a substrate support member mounted in the plasma processing region and adapted to support a substrate at a plurality of vertically spaced apart positions, a first RF transmitting device positioned to transmit RF energy to the plasma processing region, a first RF power source connected to the RF transmitting device, a second RF transmitting device positioned to transmit RF energy to the plasma processing region, a second RF power source connected to the RF transmitting device, an oxidizing gas source in communication with the plasma processing region, and a controller that is connected to the first RF power source, the second RF power source, and the gas source, wherein the controller is adapted to control the RF energy delivered to the first RF transmitting device, the RF energy delivered to the second RF transmitting device, and the gases delivered to the plasma processing region from the oxidizing gas source.

The present invention generally provides a method of plasma processing a substrate. The method comprises moving the substrate to a first of a plurality of processing positions in a plasma processing region of a plasma processing chamber, flowing an oxidizing gas mixture into the plasma processing region, generating a plasma in the plasma processing region at a substrate surface temperature of no more than about 550° C. to form an oxidized surface on the substrate, moving the substrate to a second of the plurality of processing positions, and forming a dielectric layer on the surface of the substrate to form a gate dielectric layer having a thickness from about 100 Å to about 6000 Å.

The present invention generally provides a method of plasma processing a substrate. The method comprises moving the substrate to a first of a plurality of processing positions in a plasma processing region of a plasma processing chamber, flowing an oxidizing gas mixture into the plasma processing region, generating a plasma in the plasma processing region at a substrate surface temperature of no more than about 550° C. using a first RF transmitting device, moving the substrate to a second of a plurality of processing positions in a plasma processing region of a plasma processing chamber, flowing a dielectric layer forming gas mixture into the plasma processing region; and generating a plasma in the plasma processing region at a substrate surface temperature of no more than about 550° C. using a second RF transmitting device to form a dielectric layer on the surface on the substrate.

The present invention generally provides a cluster tool for forming a high quality gate oxide layer on a substrate. The cluster tool comprises a plurality of plasma processing chambers adapted for forming an oxidized surface on the substrate and depositing a dielectric layer on the substrate to form a gate dielectric layer, and a controller configured to maintain the substrate at a temperature no more than about 550° C.

The present invention generally provides a cluster tool for forming a high quality gate oxide layer on a substrate. The cluster tool comprises a first chamber adapted to form an oxidized surface on a substrate at a temperature no more than about 550° C., and a second chamber adapted to deposit a dielectric layer onto the oxidized surface on the substrate at a temperature no more than about 550° C.

The present invention generally provides a plasma chamber for plasma processing a substrate, comprising one or more chamber walls defining a plasma processing region, a substrate support member mounted in the plasma processing region and adapted to support the substrate at a plurality of vertically spaced apart plasma processing positions, an RF coil positioned to transmit RF energy to the plasma processing region, an RF power source connected to the RF coil, a gas distribution plate positioned to transmit RF energy to the plasma processing region, an RF power source connected to the gas distribution plate, and an oxidizing gas source in communication with the plasma processing region.

The present invention generally provides a plasma chamber for plasma processing a substrate, comprising one or more chamber walls defining a plasma processing region, a substrate support member mounted in the plasma processing region and adapted to support the substrate at a plurality of vertically spaced apart plasma processing positions, the substrate support is positioned to transmit RF energy to the plasma processing region, wherein the RF energy is delivered to the substrate support from a RF power source, a gas distribution plate mounted in the plasma processing region, wherein the gas distribution plate is grounded, and an oxidizing gas source in communication with the plasma processing region.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 (Prior Art) is a schematic diagram of prior art single thin film transistor structure.

FIG. 2 is a cross-sectional view of a plasma process chamber that may be used to practice embodiments described herein, where the substrate support is in a low-processing-position.

FIGS. 2A and 2B are cross-sectional views of an inductively coupled source assembly illustrated in FIG. 2-4 that may be used to practice embodiments described herein.

FIG. 3 is a cross-sectional view of a plasma processing chamber that may be used to practice embodiments described herein, where the substrate support is in a top-processing-position.

FIG. 4 is a cross-sectional view of a plasma processing chamber that may be used to practice embodiments described herein, where the substrate support is in a substrate-exchange-position.

FIG. 5 is a cross-sectional view of a plasma processing chamber that may be used to practice embodiments described herein, in which the surface area of the grounded surfaces in the plasma processing chamber has been increased from the embodiments shown in FIGS. 2-4.

FIG. 6 is a top view of a plasma processing chamber that may be used to practice embodiments described herein.

FIG. 7 is an isometric view of a chamber useful to practice embodiments described herein.

FIG. 8 is a cluster tool for processing a high quality gate oxide layer in accordance with one embodiment of the present invention.

### DETAILED DESCRIPTION

The present invention generally provides an apparatus and method for processing a surface of a substrate using an inductively coupled high density plasma. In general, aspects of the present invention can be used for flat panel display processing, semiconductor processing, solar cell processing, or any other substrate processing. The invention is illustratively described below in reference to a chemical vapor deposition system, processing large area substrates, such as a plasma enhanced chemical vapor deposition (PECVD) system, available from AKT, a division of Applied Materials, Inc., Santa Clara, Calif. However, it should be understood that the apparatus and method may have utility in other system configurations, including those systems configured to process round substrates.

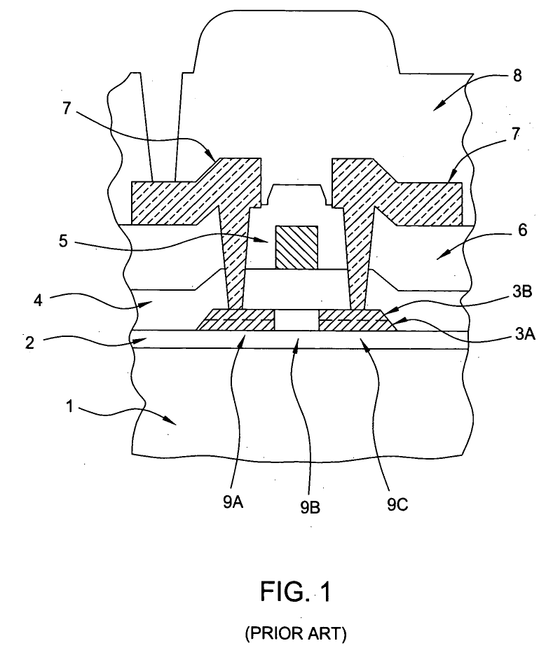

FIG. 1 illustrates a cross-sectional schematic view of a thin film transistor structure. The optically transparent optically transparent substrate 1 may comprise a material that is essentially optically transparent in the visible spectrum, such as, for example, glass or clear plastic. The optically transparent substrate 1 may be of varying shapes or dimensions. Typically, for TFT applications, the optically transparent substrate 1 is a glass substrate with a surface area greater than about 2000 cm².

A bulk semiconductor layer 3A is formed on the optically transparent substrate 1. The bulk semiconductor layer 3A may comprise a polycrystalline silicon (polysilicon) or amorphous silicon (α-Si) layer, which could be deposited using a PECVD system by conventional methods known to the art. Bulk semiconductor layer 3A may be in the range of about 100 Å to about 3000 Å thick. In one embodiment the bulk semiconductor layer 3A is a doped n-type or p-type polysilicon or α-Si layer. In one embodiment another polysilicon or α-Si second semiconductor layer 3B may be deposited on the bulk semiconductor layer 3A to a thickness within a range of about 100 Å to about 3000 Å.

Between the optically transparent substrate 1 and the bulk semiconductor layer 3A, there may be an optional insulating material 2, for example, such as a silicon dioxide (SiO₂) or silicon nitride (SiN) layer.

A gate dielectric layer 4 is formed on the bulk semiconductor layer 3A (or the second semiconductor layer 3B). In one aspect of the present invention the gate dielectric layer 4 is made from a silicon dioxide grown by consuming some of the already deposited silicon layer using a high density plasma oxidation (HDPO) process, described below. In another embodiment a multilayer gate dielectric layer 4 is formed using the HDPO process to grow a silicon dioxide film and then a plasma enhanced chemical vapor deposited silicon dioxide, silicon oxynitride (SiON), and/or silicon nitride (SiN) film is deposited on the HDPO process film. In one embodiment a high density plasma enhanced CVD process is utilized to deposit the second layer. The total gate dielectric layer 4 may be formed to a thickness in the range of about 100 Å to about 6000 Å.

A gate electrode layer 5 is formed on the gate dielectric layer 4. The gate electrode layer 5 comprises an electrically conductive layer that controls the movement of charge carriers within the TFT device. The gate electrode layer 5 may comprise a metal such as, for example, aluminum (Al), tungsten (W), chromium (Cr), tantalum (Ta), polysilicon or combinations thereof, among others. The gate electrode layer 5 may be formed using conventional deposition, lithography and etching techniques. Also, by use of conventional deposition, lithography and etching techniques an insulation layer 6, electrical source and drain contacts 7 and a passivation layer 8 are then formed over the gate electrode layer 5.

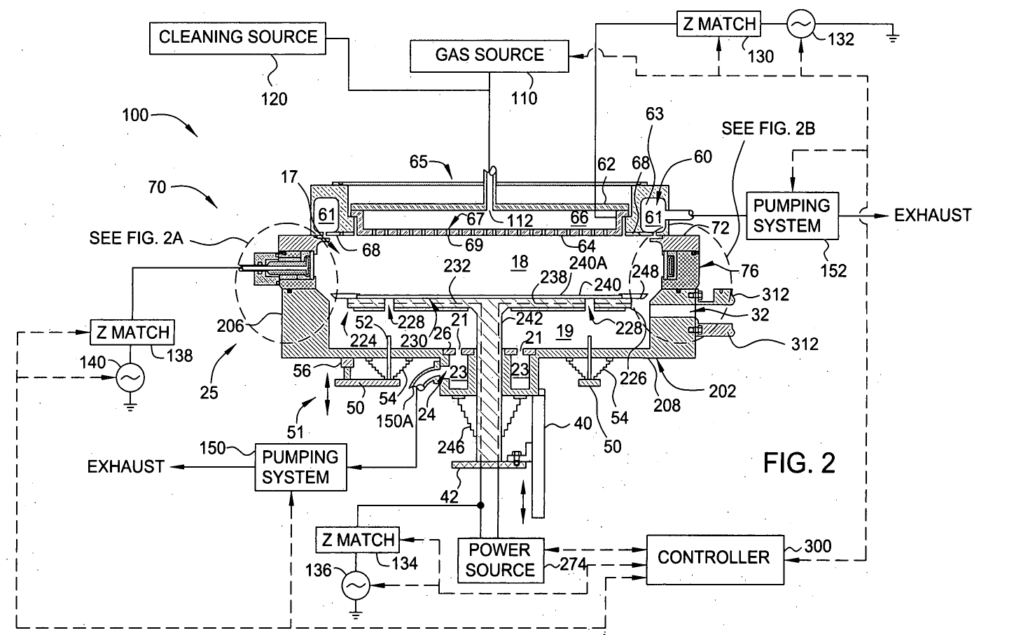

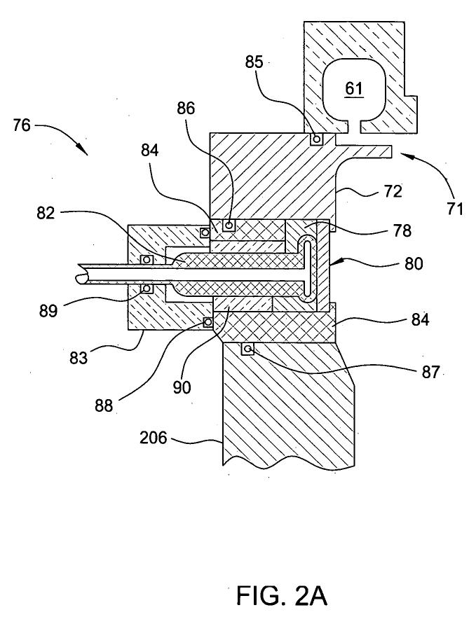

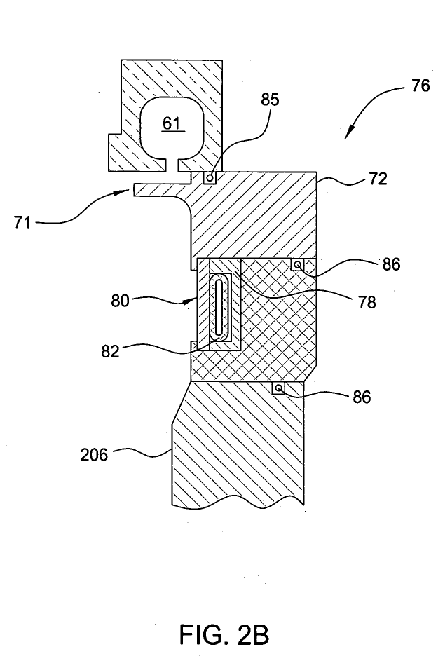

FIG. 2 is a schematic cross-sectional view of a plasma processing chamber 100. The plasma processing chamber 100 generally includes a gas distribution assembly 64, an inductively coupled source assembly 70, and a lower chamber assembly 25. A chamber volume 17, which is made up of an process volume 18 and a lower volume 19, defines a region in which the plasma processing will occur in the plasma processing chamber 100 and is enclosed by the gas distribution assembly 64, the inductively coupled source assembly 70, and the lower chamber assembly 25.

The lower chamber assembly 25 generally includes a substrate lift assembly 51, a substrate support 238 and a processing chamber base 202. The processing chamber base 202 has chamber walls 206 and a chamber bottom 208 that partially define a lower volume 19. The processing chamber base 202 is accessed through the access port 32 in the chamber walls 206. The access port 32 defines the region through which a substrate 240 can be moved in and out of the processing chamber base 202. The chamber walls 206 and chamber bottom 208 may be fabricated from a unitary block of aluminum or other material(s) compatible with processing.

A temperature controlled substrate support 238 is connected to the processing chamber base 202. The substrate support 238 supports a substrate 240 during processing. In one embodiment, the substrate support 238 comprises an aluminum body 224 that encapsulates at least one embedded heater 232. The embedded heater 232, such as a resistive heating element, is disposed in the substrate support 238. The embedded heater 232 is coupled to a power source 274, which can controllably heat the substrate support 238 and the substrate 240 positioned thereon to a predetermined temperature by use of a controller 300. Typically, in most CVD processes, the embedded heater 232 maintains the substrate 240 at a uniform temperature range between about 60° C. for plastic substrates to about 550° C. for glass substrates.

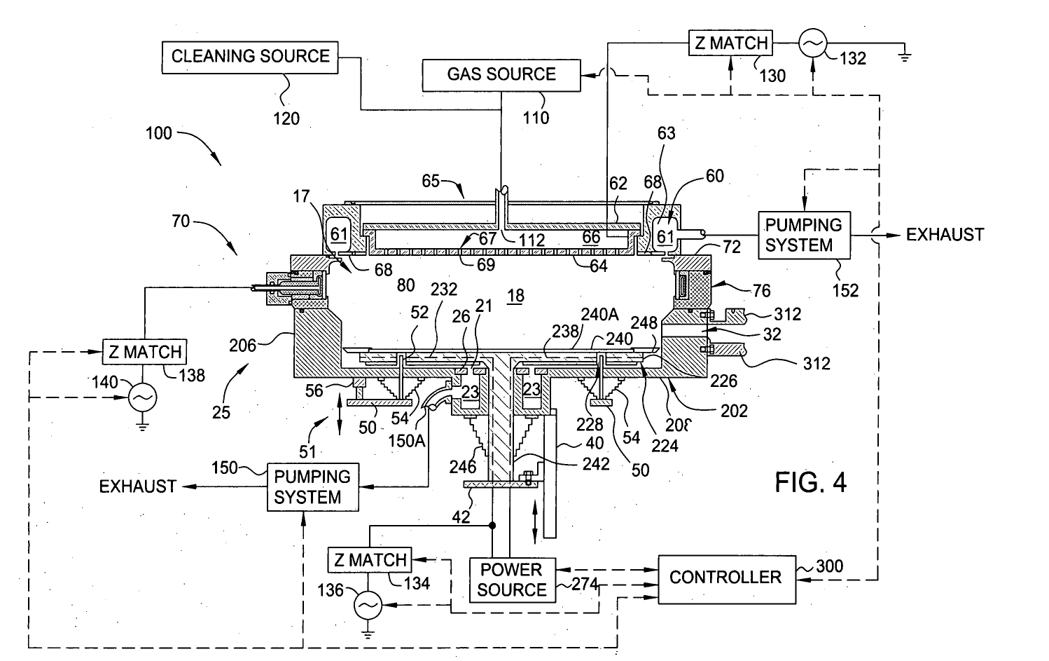

Generally, the substrate support 238 has a back side 226, a front side 234 and a stem 242. The front side 234 supports the substrate 240, while the stem 242 is coupled to the back side 226. The stem base 42 attached to the stem 242 is connected to a lift assembly 40 that moves the substrate support 238 between various positions, as shown in FIGS. 2-4. The transfer position, shown in FIG. 4, allows the system robot (not shown) to freely enter and exit the plasma processing chamber 100 without interference with the substrate support 238 and/or the lift pins 52. The stem 242 additionally provides a conduit for electrical and thermocouple leads between the substrate support 238 and other components of the cluster tool 310. The lift assembly may comprise a pneumatic or motorized lead-screw type lift assembly commonly used in the art to supply the force necessary to counteract gravity and atmospheric pressure forces acting on the substrate support 238 when the plasma processing chamber 100 is under vacuum, and to accurately position the support assembly in the plasma processing chamber 100.

A bellows 246 is coupled between substrate support 238 (or the stem 242) and the chamber bottom 208 of the processing chamber base 202. The bellows 246 provides a vacuum seal between the chamber volume 17 and the atmosphere outside the processing chamber base 202, while facilitating vertical movement of the substrate support 238.

The substrate support 238 additionally supports a substrate 240 and a circumscribing shadow frame 248. Generally, the shadow frame 248 prevents deposition on the edge of the substrate 240 and on the substrate support 238. In one embodiment the shadow frame 248 is separated from the substrate 240 and the substrate support 238 by use of a feature attached to the substrate lift assembly 51 (not shown). In another embodiment the shadow frame 248 is deposited on a capturing feature (not shown), which is mounted in the plasma processing chamber 100, as the substrate support moves down from the processing position, to allow the substrate support 238 to separate from the shadow frame 248 as it rests on the capture feature. The capture feature embodiment or the feature attached to the substrate lift assembly embodiment will thus help facilitate the removal of the substrate 240 from the substrate support 238 and thus the plasma processing chamber 100.

The substrate support 238 has a plurality of holes 228 disposed therethrough to accept a plurality of lift pins 52. The lift pins 52 are typically made from ceramic, graphite, ceramic coated metal, or stainless steel. The lift pins 52 may be actuated relative to the substrate support 238 and process chamber base 202 by use of a lift plate 50 that can move the lift pins 52 from a retracted position (as shown in FIG. 2) to a raised position (not shown). The lift bellows 54 attached to each of the lift pins 52 and the chamber bottom 208, are used to isolate the lower volume 19 from the atmosphere outside of the plasma process chamber 100, while also allowing the lift pins 52 to move from the retracted position (as shown in FIG. 2) to the raised position (not shown). The lift plate 50 is actuated by use of a lift actuator 56. When the lift pins 52 are in the raised position and the substrate support 238 is in the transfer position the substrate 240 is lifted above the top edge of the access port 32 so that the system robot can enter and exit from the plasma processing chamber 100.

The lid assembly 65 typically includes an entry port 112 through which process gases, provided by the gas source 110, are introduced into the process volume 18 after passing through the gas distribution plate 64. Proper control and regulation of the gas flows from the gas source 110 to the entry port 112 are performed by mass flow controllers (not shown) and a controller 300. The gas source 110 may include a plurality of mass flow controllers (not shown). The term “mass flow controllers”, as used herein, refers to any control valves capable of providing rapid and precise gas flow to the plasma processing chamber 100. The entry port 112 allows process gases to be introduced and uniformly distributed in the plasma processing chamber 100. Additionally, the entry port 112 may optionally be heated to prevent condensation of any reactive gases within the manifold.

The entry port 112 is also coupled to a cleaning source 120. The cleaning source 120 typically provides a cleaning agent, such as disassociated fluorine, that is introduced into the process volume 18 to remove deposition by-products and stray deposited material left over after the completion of prior processing steps.

The lid assembly 65 provides an upper boundary to the process volume 18. The lid assembly 65 typically can be removed from the chamber base 202 and/or the inductively coupled source assembly 70 to service components in the plasma processing chamber 100. Typically, the lid assembly 65 is fabricated from aluminum (Al) or an anodized aluminum body.

In one embodiment the lid assembly 65 includes a pumping plenum 63 which is coupled to an external vacuum pumping system 152. The pumping plenum 63 is utilized to uniformly evacuate the gases and processing by-products from the process volume 18. The pumping plenum 63 is generally formed within, or attached to, the chamber lid 60 and covered by a plate 68 to form the pumping channel 61. To assure uniform evacuation of the process volume 18 a gap is formed between the plate 68 and chamber lid 60, to create a small restriction to gas flow into the pumping channel 61. In one embodiment a shadow feature 71 formed on the lid support member 72 of the inductively coupled source assembly 70 may also be used to supply an additional restriction to further assure uniform evacuation of the process volume 18. The vacuum pumping system 152 will generally contain a vacuum pump which may be a turbo pump, rough pump, and/or Roots Blower™ as required to achieve the desired chamber processing pressures.

In another embodiment a pumping plenum 24, found in the lower chamber assembly 25, is used to uniformly evacuate the gases and processing by-products from the process volume 18 by use of a vacuum pumping system 150. The pumping plenum 24 is generally formed within, or attached to the chamber bottom 208 and that may be covered by a plate 26 to form a enclosed pumping channel 23. The plate 26 generally contains a plurality of holes 21 (or slots) to create a small restriction to gas flow into the pumping channel 23 to assure uniform evacuation of the chamber volume 17. The pumping channel 23 is connected to the vacuum pumping system 150 through a pumping port 150A. The vacuum pumping system 150 generally contains a vacuum pump which may be a turbo pump, rough pump, and/or Roots Blower™ as required to achieve the desired chamber processing pressures. In one embodiment, as shown in FIG. 2-4, the pumping plenum 24 is symmetrically distributed about the center of the processing chamber to ensure even gas evacuation from the process volume 18. In another embodiment the pumping plenum 24 is non-symmetrically positioned (not shown) in the lower chamber assembly 25.

In another embodiment a pumping plenum 24 and a pumping plenum 63 are both used to evacuate the process volume 18. In this embodiment the relative flow rate of gas removed from the process volume 18, by use of vacuum pumping system 152, and from the lower volume 19, by use of vacuum pumping system 150, may be optimized to improve plasma processing results and reduce the leakage of the plasma and processing by-products into the lower volume 19. Reducing the leakage of the plasma and processing by-products will reduce the amount of stray deposition on the lower chamber assembly 25 components and thus reduce the clean time and/or the frequency of using the cleaning source 120 to remove these unwanted deposits.

A gas distribution plate 64 is coupled to a top plate 62 of the lid assembly 65. The shape of the gas distribution plate 64 is typically configured to substantially follow the profile of the substrate 240. The gas distribution plate 64 includes a perforated area 67, through which process and other gases supplied from the gas source 110 are delivered to the process volume 18. The perforated area 67 of the gas distribution plate 64 is configured to provide uniform distribution of gases passing through the gas distribution plate 64 into the process volume 18. Gas distribution plates that may be adapted to benefit from the invention are described in commonly assigned U.S. patent application Ser. No. 10/337,483, filed Jan. 7, 2003 by Blonigan et al.; U.S. Pat. No. 6,477,980, issued Nov. 12, 2002 to White et al.; and U.S. patent application Ser. Nos. 10/417,592, filed Apr. 16, 2003 by Choi et al., which are hereby incorporated by reference in their entireties.

The gas distribution plate 64, as shown in FIGS. 2-4, may be formed from a single unitary member. In other embodiments the gas distribution plate 64 can be made from two or more separate pieces. A plurality of gas passages 69 are formed through the gas distribution plate 64 to allow a desired distribution of the process gases to pass through the gas distribution plate 64 and into the process volume 18. A plenum 66 is formed between the gas distribution plate 64 and the top plate 62. The plenum 66 allows gases flowing into the plenum 66 from the gas source 110 to uniformly distribute across the width of the gas distribution plate 64 and flow uniformly through the gas passages 69. The gas distribution plate 64 is typically fabricated from aluminum (Al), anodized aluminum, or other RF conductive material. The gas distribution plate 64 is electrically isolated from the chamber lid 60 by an electrical insulation piece (note shown).

Referring to FIGS. 2, 2A and 2B, the inductively coupled source assembly 70 generally contains a RF coil 82, a support structure 76, a cover 80, and various insulating pieces (e.g., an inner insulation 78, an outer insulation 90, etc.) The supporting structure 76 generally contains a supporting member 84 and a lid support member 72, which are grounded metal parts which support the lid assembly 65's components. The RF coil 82 is supported and surrounded by a number of components which prevent the RF power delivered to the coil from the RF power source 140 from arcing to the support structure 76 or incurring significant losses to the grounded chamber components (e.g., processing chamber base 202, etc.). A cover 80, which is a thin continuous ring, band or array of overlapping sections is attached to the supporting structure 76 components. The cover 80 is intended to shield the RF coil 82 from interacting with the plasma deposition chemistries or from being bombarded by ions or neutrals generated during plasma processing or by chamber cleaning chemistries. The cover 80 is made from a ceramic material (e.g., alumina or sapphire) or other process-compatible dielectric material. Also, various insulating pieces, for example, the inner insulation 78 and the outer insulation 90, are used to support and isolate the RF coil 82 from the electrically grounded supporting structure 76. The insulating pieces are generally made from an electrically insulating materials, for example, Teflon or ceramic materials. A vacuum feedthrough 83 attaches to the supporting structure 76 to hold and support the RF coil 82 and prevent atmospheric leakage into an evacuated process volume 18. The supporting structure 76, the vacuum feedthrough 83 and the various o-rings 85, 86, 87, 88 and 89 form a vacuum tight structure that supports the RF coil 82 and the gas distribution assembly 64, and allows the RF coil 82 to communicate with the process volume 18 with no conductive barriers to inhibit the RF generated fields.

The RF coil 82, as shown in FIGS. 2-5, is connected to a RF power sources 140 through RF impedance match networks 138. In this configuration the RF coil 82 acts as an inductively coupled RF energy transmitting device that can generate and control the plasma generated in the process volume 18. In one embodiment, dynamic impedance matching may be provided to the RF coil 82. By use of the controller 300, the RF coil 82, which is mounted at the periphery of the process volume 18, is able to control and shape a plasma generated near the substrate surface 240A. In one embodiment the RF coil 82, shown in FIGS. 2-5, is a single turn coil used to control a plasma generated in the chamber volume 17. In another embodiment a multi-turn coil is used to control the plasma shape and density.

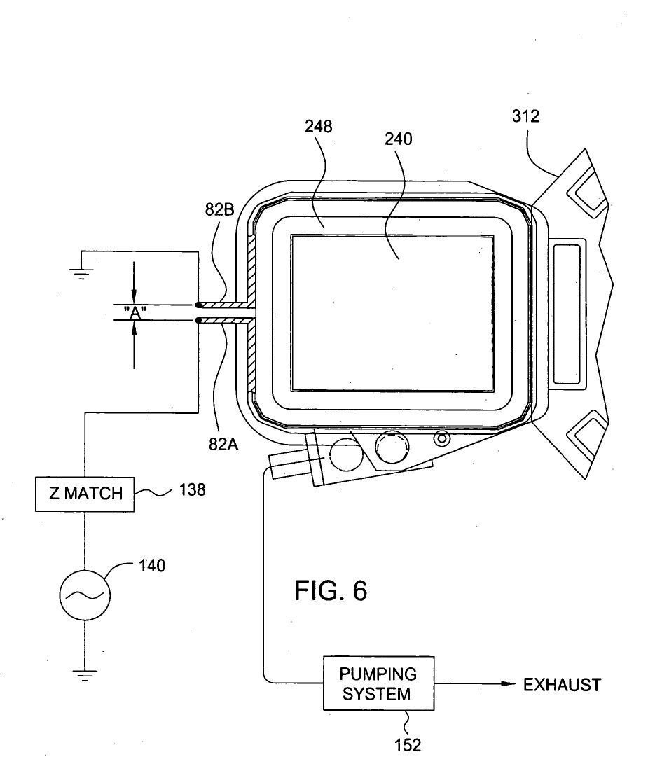

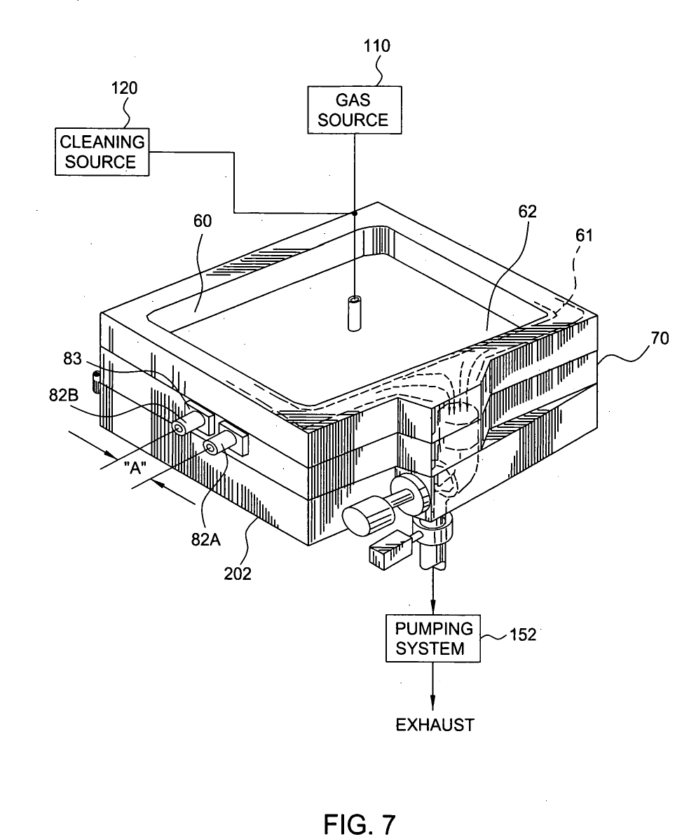

In some configurations the coil ends of a single turn coil can affect the uniformity of the plasma generated in the plasma processing chamber 100. When it is not practical or desired to overlap the ends of the coil, a gap region “A”, as shown in FIGS. 6 and 7, may be left between the coil ends. The gap region “A,” due to the missing length of coil and RF voltage interaction at the input end 82A and output end 82B of the coil, will result in weaker RF generated magnetic field near the gap “A”. The weaker magnetic field in this region can have a negative effect on the plasma uniformity in the chamber. To resolve this possible problem, the reactance between the RF coil 82 and ground can be continuously or repeatedly tuned during processing by use of a variable inductor, which shifts or rotates the RF voltage distribution, and thus the generated plasma, along the RF coil 82, to time average any plasma non-uniformity and reduce the RF voltage interaction at the ends of the coil. An exemplary method of tuning the reactance between the RF coil 82 and ground, to shift the RF voltage distribution in a coil, is further described in the United States Patent Application U.S. Pat. No. 6,254,738, entitled “Use of Variable Impedance Having Rotating Core to Control Coil Sputtering Distribution”, filed on Mar. 31, 1998, which is incorporated by reference herein to the extent not inconsistent with the claimed aspects and disclosure herein. As a consequence, the plasma generated in the process volume 18 is more uniformly and axially symmetrically controlled, through time-averaging of the plasma distribution by varying the RF voltage distribution. The RF voltage distributions along the RF coil 82 can influence various properties of the plasma including the plasma density, RF potential profiles, and ion bombardment of the plasma-exposed surfaces including the substrate 240

In one embodiment the gas distribution plate 64 is RF biased so that a plasma generated in the process volume 18 can be controlled and shaped by use of an attached impedance match element 130, an RF power source 132 and the controller 300. The RF biased gas distribution plate 64 acts as a capacitively coupled RF energy transmitting device that can generate and control the plasma in the process volume 18.

In another embodiment an RF power source 136 applies RF bias power to the substrate support 238 through an impedance match element 134. By use of the RF power source 136, the impedance match element 134 and the controller 300 the user can control the generated plasma in the process volume 18, control plasma bombardment of the substrate 240 and vary the plasma sheath thickness over the substrate surface 240A. In another embodiment, the RF power source 136 and the impedance match element 134 are replaced by one or more connections to ground (not shown) thus grounding the substrate support 238.

To control the plasma processing chamber 100, process variables and components, along with the other cluster tool 310 components, a controller 300 is adapted to control all aspects of the complete substrate processing sequence. The controller 300 is adapted to control the impedance match elements (i.e., 130, 134, and 138), the RF power sources (i.e., 132, 136 and 140) and all other elements of the plasma processing chamber 100. The plasma processing chamber 100's plasma processing variables are controlled by use of a controller 300, which is typically a microprocessor-based controller. The controller 300 is configured to receive inputs from a user and/or various sensors in the plasma processing chamber and appropriately control the plasma processing chamber components in accordance with the various inputs and software instructions retained in the controller's memory. The controller 300 generally contains memory and a CPU which are utilized by the controller to retain various programs, process the programs, and execute the programs when necessary. The memory is connected to the CPU, and may be one or more of a readily available memory, such as random access memory (RAM), read only memory (ROM), floppy disk, hard disk, or any other form of digital storage, local or remote. Software instructions and data can be coded and stored within the memory for instructing the CPU. The support circuits are also connected to the CPU for supporting the processor in a conventional manner. The support circuits may include cache, power supplies, clock circuits, input/output circuitry, subsystems, and the like all well known in the art. A program (or computer instructions) readable by the controller 300 determines which tasks are performable in the plasma processing chamber. Preferably, the program is software readable by the controller 300 and includes instructions to monitor and control the plasma process based on defined rules and input data.

Plasma Processing

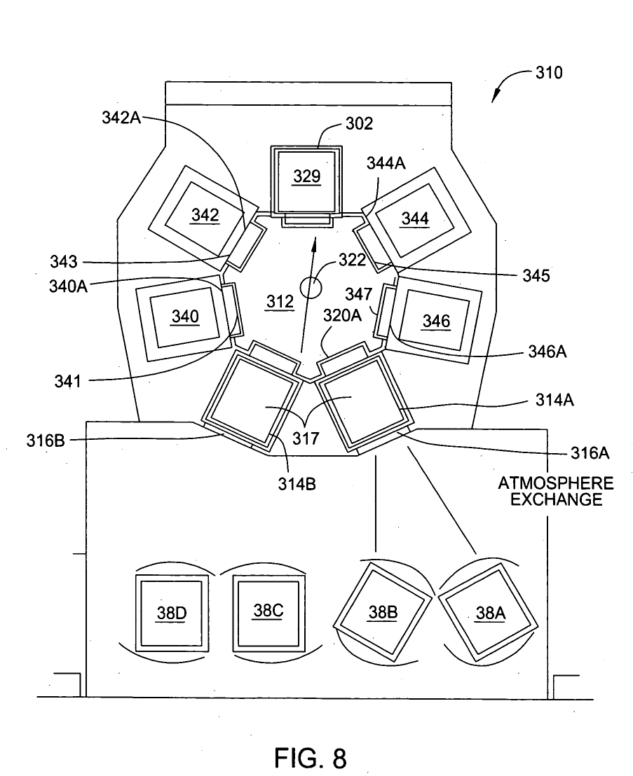

In operation, the plasma processing chamber 100 is evacuated to a predetermined pressure/vacuum by the vacuum pumping system 150 and/or the vacuum pumping system 152, so that the plasma processing chamber 100 can receive a substrate 240 from a system robot (not shown) mounted in the central transfer chamber 312 which is also under vacuum. To transfer a substrate 240 to the chamber the slit valve (See items 341, 343, 345 and 347 in FIG. 8), which seals off the plasma processing chamber 100 from the central transfer chamber 312, opens to allow the system robot to extend through the access port 32 in the processing chamber base 202. The lift pins 52 then remove the substrate 240 from the extended system robot. The system robot then retracts from the plasma processing chamber 100 and the chamber slit valve closes to isolate the plasma processing chamber 100 from the central transfer chamber 312. The substrate support 238 then lifts the substrate 240 from the lift pins 52 and moves the substrate 240 to a desired processing position.

Once the substrate 240 has been received, the following general plasma processing steps are used to complete the processing sequence on the substrate 240. First, after the substrate 240 has been picked up off the lift pins the substrate support 238 is moved to a desired processing position and the plasma processing chamber is evacuated to a predetermined base pressure. Once the predetermined base pressure is achieved, specific flow rate of one or more process gases are introduced into the chamber volume 17 through the gas distribution plate 64 from the gas sources 110, while the vacuum pumping system(s) continue to evacuate the chamber volume 17, such that an equilibrium processing pressure is achieved. The controller 300 adjusts the processing pressure by either throttling the communication of the vacuum pumping systems (i.e., 150 and/or 152) and/or adjusting the flow rate of the process gases being introduced from the gas source 110. Once a desired pressure and gas flows are established, the respective RF power supplies may be activated to generate and control the plasma generated in the process volume 18. Power can be independently supplied to the RF coil 82, gas distribution plate 64, and/or the substrate support 238 by use of the controller 300. By varying the RF power to the RF coil 82, the gas distribution plate 64 and/or the substrate support 238 the density of the plasma generated in the process volume 18 can be varied, since the plasma ion density is directly affected by the generated magnetic and/or electric field strength. The ion density of the plasma may also be increased or decreased through adjustment of the processing pressure or the RF power delivered to the RF coil 82 and/or the gas distribution plate 64. After the various chamber processing steps, described below, have been performed on the substrate, it is then removed from the plasma processing chamber 100 by raising the lift pins 52, lowering the substrate support 238 to deposit the substrate 240 on the raised lift pins 52, opening the slit valve (not shown), extending the system robot into the chamber, lowering the lift pins 52 to deposit the substrate 240 on the system robot blade (not shown), then retracting the system robot and then closing the slit valve.

High Quality Gate Oxide Formation

Embodiments of the present invention describe a process of forming a high quality gate dielectric layer to ensure that a stable, repeatable and desired electrical performance is achieved from the fabricated TFT device. Embodiments of the present invention generally describe one or more process steps used to form the high quality gate dielectric layer in the above described plasma processing chamber 100.

In one embodiment of this invention a single high density plasma oxidation process (HDPO), described below, is used to form the gate dielectric layer. The HDPO process layer in this embodiment may be about 20 to about 1000 Angstroms (Å) in thickness, but preferably in a range between about 50 and about 150 Å.

In another embodiment a two layer film is formed by first performing the HDPO process and then a CVD film on top of the first HDPO process layer. In this embodiment the CVD film may be SiO₂ deposited using a PECVD tetraethyloxysilane (TEOS) (or tetraethylorthosilicate (TEOS)) type deposition process. The HDPO process layer in this embodiment may be from about 20 to about 500 Angstroms (Å) in thickness, but preferably in a range between about 50 and about 150 Å. The overall gate dielectric layer 4 thickness may be in the range of about 100 Å to about 6000 Å.

High Density Plasma Oxidation Process

The HDPO process is completed by exposing the silicon substrate surface 240A to a plasma generated using an oxygen-containing gas or mixture of gasses delivered to the process volume 18 through the gas distribution plate 64 from the gas source 110. The HDPO process is a plasma oxidation process. Conventional thermal type oxidation processes used to oxidize silicon often require very high temperatures, usually >900° C. Therefore, to minimize the required temperature to form a high quality gate dielectric layer, aspects of the invention may be used at low temperatures (<550° C.) to form the high quality gate dielectric layer. Typically the HDPO process will be run at a temperature in a range between about 60° C. and about 550° C. In conventional thermal oxidation processes reducing the processing temperature will reduce the growth rate of the oxide layer which lengthens the chamber processing time, and thus system throughput. To enhance the growth rate, and thus reduce the chamber processing time, the HDPO process utilizes RF energy to enhance the gate oxide growth rate. It is believed that the HDPO process is able to enhance the growth rate since the application of RF energy will 1) enhance the disassociation or ionization of the reactive species, 2) increase the energy (or activity) of the reactive species, 3) add energy to the substrate surface 240A through ion and neutral bombardment, and 4) expose the substrate surface 240A to thermal radiation created by the generation of the high density plasma.

In one embodiment the HDPO process entails controlling the RF power delivered to the RF coil 82 to control the plasma ion density of the plasma created in the process volume 18 over the substrate surface 240A. Typically RF power delivered to the RF coil 82 may be from about 250 to about 25000 Watts/m² at a frequency from about 0.3 MHz to greater than 10 GHz. Preferably the RF frequency is about 13 MHz to about 80 MHz. In one embodiment dynamic impedance matching is provided to the RF coil 82 by frequency tuning, impedance matching network tuning or frequency tuning with forward power servoing.

In another embodiment the HDPO process plasma is generated and controlled from RF energy delivered to the gas distribution plate 64. Typically RF power delivered to the gas distribution plate 64 may be from about 250 to about 25000 Watts/m² at a frequency from about 0.3 MHz to greater than 10 GHz. Preferably the RF frequency is about 13 MHz to about 80 MHz. In one embodiment dynamic impedance matching is provided to the gas distribution plate 64 by frequency tuning, impedance matching network tuning or frequency tuning with forward power servoing.

In another embodiment the HDPO process is completed by delivering RF energy to the RF coil 82 and the gas distribution plate 64 at the same time. In this case the RF power delivered to the gas distribution plate 64 and the RF coil 82 may be in a range between about 250 and about 25000 Watts/m² at a frequency from about 0.3 MHz to greater than 10 GHz. Preferably the RF frequency is about 13 MHz to about 80 MHz. To avoid interaction of the RF power delivered to the RF coil 82 and the gas distribution plate 64, the frequency of the RF power delivered to each device may be intentionally driven to a slightly different RF frequency. For example, the RF coil 82 may be run at about 13.56 MHz and the gas distribution plate may be driven at about 12.56 MHz or vise versa.

In yet another embodiment the substrate support 238 is RF biased or grounded while RF energy is delivered to the RF coil 82 and/or a the gas distribution plate 64. In this case the RF power delivered to the gas distribution plate 64, the RF coil 82, and the substrate support 238 may be in a range between about 250 and about 25000 Watts/m² at a frequency from about 0.3 MHz to greater than 10 GHz. Preferably the RF frequency is about 13 MHz to about 80 MHz. In this case it may also be beneficial to drive the RF power delivered to the RF coil 82, substrate support 238, and the gas distribution plate 64 at different frequencies to reduce any unwanted effects caused by the interaction of the generated RF fields.

The plasma ion density created during the HDPO process will vary depending upon various processing parameters, for example, the type of process gas or gas mixture introduced into the chamber, the chamber pressure, and/or the energy (e.g., RF power, etc.) delivered into the chamber to excite the gas or gas mixture. In one embodiment the HDPO process gases may include a gas containing a source of oxygen, for example, a pure oxygen gas or oxygen mixed with another gas, such as, helium, hydrogen, argon, xenon, krypton or combinations thereof. In one embodiment only a pure oxygen gas is used. In another embodiment H₂O may be injected into the chamber to enhance the oxide growth process.

In one embodiment, in order to generate and sustain the high density plasma used in the HDPO process, oxygen gas and one or more other gasses (e.g., helium, argon, etc.) are injected into the chamber volume 17 to achieve a chamber pressure from about 1 mTorr to about 0.5 Torr. Preferably, the HDPO process uses oxygen gas and helium at a pressure in a range between about 3 mTorr and about 250 mTorr.

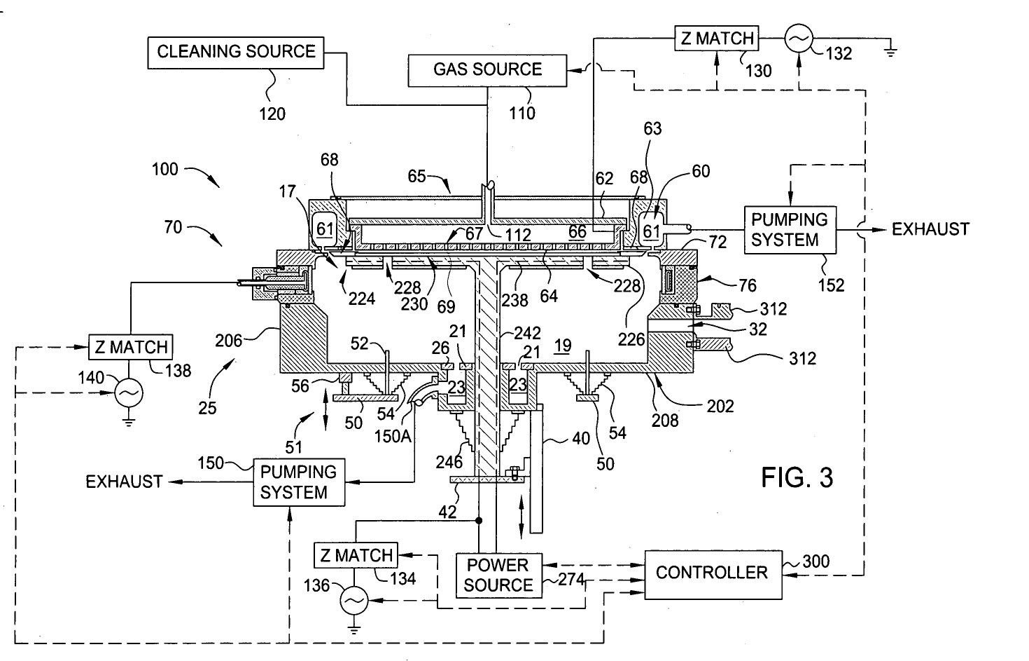

The interaction of the plasma with the substrate surface 240A, while affected by the generated plasma density, is also affected by the position of the substrate in the plasma chamber and the effect of floating, grounding or RF biasing of the substrate support 238. Generally, the farther the substrate is away from the plasma generating source(s) the less interaction the substrate surface 240A will have the generated plasma. The optimal position of the substrate support to form a high quality gate oxide layer depends on the plasma density at the surface of the substrate, the energy of the ions bombarding the substrate surface, processing temperature and the desired chamber processing time. FIG. 2 shows a schematic cross-sectional view of the plasma processing chamber in which the substrate support is mounted in a middle position in the process chamber, which in one embodiment is optimal for forming an HDPO layer. FIG. 3 shows a schematic cross-sectional view of the plasma processing chamber in which the substrate support is positioned close to the surface of the gas distribution plate 64, which in one embodiment is optimal for forming a conventional PECVD oxide layer by applying RF power to the gas distribution plate 64. Since the HDPO layer growth rate and process uniformity are affected by the interaction of the substrate surface with the generated plasma, the processing position of the substrate support may be adjusted according to the process variables found in the HDPO layer processing recipe. The optimal plasma processing position is strongly dependent on the plasma processing chamber attributes (e.g., chamber size, substrate position relative to pumping ports, etc.) and the configuration of the RF energy transmitting device(s) relative to the substrate surface. In one embodiment the processing position may be varied as the plasma ion density is adjusted during the HDPO layer processing steps. FIG. 2 illustrates a preferred position for the HDPO oxide growth process and the HDP deposition process. FIG. 3 illustrates a preferred position for the conventional PECVD deposition process. The preferred position can be measured by the height of the process volume 18, or also known as the chamber “spacing.” The spacing may be, for example, the distance between the substrate 240, mounted on the substrate supporting surface 230 of the substrate support 238, to the gas distribution plate 64, but is generally defined as the distance measure normal to the substrate surface 240A to gas distribution plate 64 (i.e., the edge of the process volume 18). In one embodiment, the spacing in a processing chamber adapted to perform the HDPO process on a 730 mm×920 mm substrate, when using one or more of the RF energy transmitting devices, may be in a range between about 50 and about 500 mm. The chamber spacing may vary as the size of the substrate increases.

FIG. 4 shows a schematic cross-sectional view of one embodiment of the plasma processing chamber 100 in which the substrate support 238 is positioned in a position at or near the bottom of the plasma processing chamber. This position is used for exchanging the processed substrate for an unprocessed one.

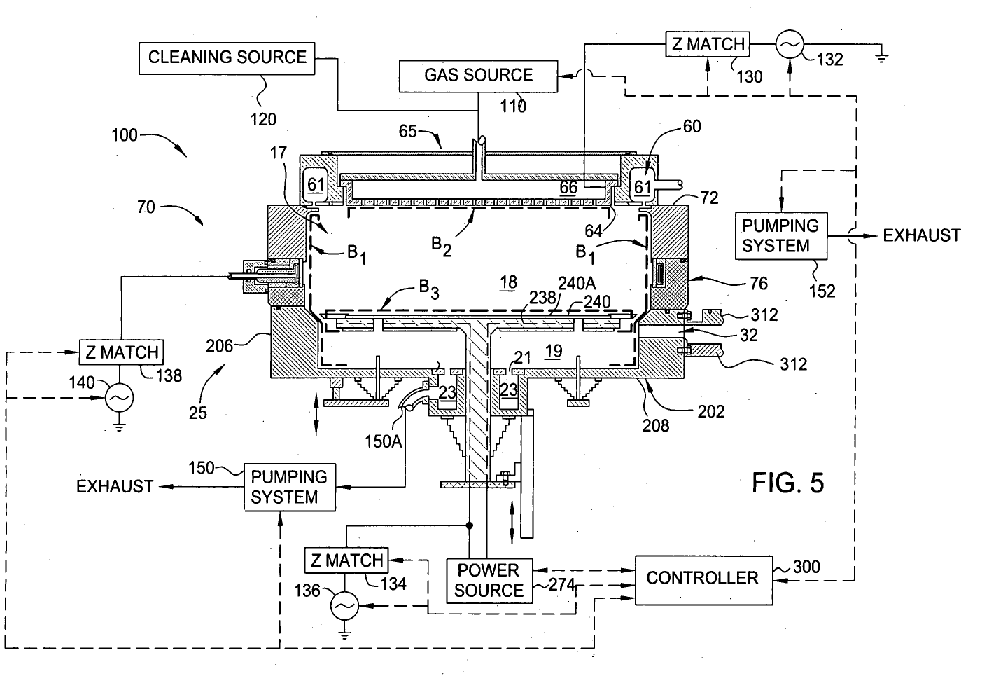

FIG. 5 illustrates a schematic cross-sectional view of one embodiment of the plasma processing chamber 100 in which the surface area of the grounded surfaces (see grounded chamber wall surface “B1” and the substrate support surface “B3” when the substrate support is grounded) in the process chamber has been increased relative to the surface area of the capacitively coupled electrode (i.e., RF energy transmission device(s) (see the gas distribution plate surface “B2” and/or the substrate support surface “B3”)) surface in contact with the process volume 18 to develop an optimum substrate bias when the substrate support is grounded, improve the uniformity of the generated plasma, and minimize the intensity of the bombardment of the grounded components including the substrate. In one embodiment, the substrate support 238 is the RF-driven electrode which has a blocking capacitor (not shown) placed between the substrate support 238 and the RF power source 136. In this embodiment, the ratio of the grounded surface area to the RF-driven electrode surface area is designed so that the substrate bias and plasma uniformity is optimized when the RF driven substrate support is used to form the HDPO layer or deposit the dielectric layer using a plasma CVD process. In this embodiment, the gas distribution plate 64 is grounded and the ratio of the total surface area of the electrode that is grounded versus substrate support surface area is preferably in a range between about 1:1 and about 2:1.

An important factor in the fabrication of semiconductor devices is the cost of ownership (COO) associated with forming a semiconductor device. The COO, while affected by a number of factors, is greatly affected by the chamber throughput or simply the processing time required to deposit the high quality gate dielectric layer. The required thickness of the gate oxide layer depends on the desired electrical performance of the TFT. In particular, the gate dielectric layer must be of a high quality (e.g., low flatband voltage (V_{fb})) so that the fabricated transistor has desirable electrical characteristics. To achieve a high quality gate dielectric layer it is important to develop a good gate dielectric layer that has very good thickness uniformity (<1%) and to have a gate dielectric layer thick enough to achieve a desired degree of step coverage and breakdown voltage. To achieve the desired step coverage and break down voltage the gate dielectric layer thickness is typically on the order of 1000 Å thick. In one embodiment the HDPO process growth rate is about 10 Å/minute. Therefore, assuming the growth rate is constant, which is unlikely, it would take approximately 100 minutes to grow a 1000 Å film. A 100 minute process time would provide an unacceptably low throughput for the plasma processing chamber 100 and thus have a negative effect on the cluster tool's COO. Therefore, either the gate dielectric layer would either need to be much thinner or a multilayer stack which has a shorter processing time needs to be used.

Chemical Vapor Deposition Process

To achieve a more economically feasible high quality gate dielectric layer, in some embodiments it may be necessary to perform the HDPO process to form a good interface and then deposit one or more layers, that have good bulk electrical properties and higher deposition rates over the HDPO layer. In one embodiment a thin HDPO process layer is formed over the channel to form a high quality dielectric interface and then one or more dielectric layers are deposited on the HDPO layer to form a high quality gate dielectric layer. In one embodiment, to minimize the plasma processing chamber's COO, a two step gate oxide formation process can be used. In this embodiment the HDPO process is performed to achieve a good gate dielectric layer interface (p-Si to HDPO layer) and then a second layer having a greater deposition rate than the HDPO process is deposited on the HDPO layer.

In one embodiment, a high density plasma (HDP) CVD deposition process is used to deposit the remaining thickness of the gate dielectric layer 4 to form a film that meets the desired physical and electrical requirements. In one embodiment, to complete the HDP CVD process a silicon-containing gas, or mixture of gasses, and an oxygen-containing gas, or mixture of gasses, are introduced to the chamber in the configuration shown in FIG. 2. Then the RF coil 82 and one or both of the other RF sources (e.g., gas distribution plate 64, substrate support 238, etc.) are used to deposit a HDP CVD oxide film over the existing HDPO layer. In another embodiment, the HDP process is completed using a silicon-containing gas (or mixture of gasses), an oxygen-containing gas and/or a nitrogen containing gas.

In one embodiment a TEOS deposition process is used to deposit the remaining thickness of the gate dielectric layer 4 to form a film that meets the desired physical and electrical requirements. An example of a typical PECVD TEOS process used on 730 mm×920 mm flat panel display substrates is embodied in a method whereby the substrate is exposed to the plasma formed by flowing about 600 sccm of tetraethyloxysilane with about 100 sccm carrier gas (e.g., helium) and about 7000 sccm oxygen in a chamber using a total gas pressure within the range of about 0.5 to about 3 torr, and a substrate temperature in the range of about 350° C. to about 550° C. Preferably, the chamber pressure is about 1 torr and the substrate temperature is about 400° C.+/−50° C. An RF power of about 2,000 Watts at a frequency of about 13.56 MHz is delivered to the gas distribution plate at a substrate process spacing in a range between about 10 and about 50 millimeters, but typically about 15 mm from the gas distribution plate 64 to achieve a deposition rate of about 1,500 Angstroms/minute. Silicon dioxide films formed by a TEOS deposition process are commonly used in the semiconductor industry as intermetal-dielectric films. The TEOS deposition process is typically performed using a dielectric layer forming gas, such as a gas mixture containing tetraethylorthosilicate, to deposit the dielectric layer. Examples of a typical process for depositing with TEOS are further described in the United States Patent Application U.S. Pat. No. 5,462,899, entitled “Chemical Vapor Deposition Method for Forming SiO₂”, filed on Oct. 31, 1995, and United States Patent Application U.S. Pat. No. 6,451,390, entitled “Deposition of TEOS Oxide Using Pulsed RF Plasma”, filed on Sep. 17, 2002, which are incorporated by reference herein to the extent not inconsistent with the claimed aspects and disclosure herein.

FIG. 3 illustrates a schematic cross-sectional view of the plasma processing chamber 100 where the substrate support 238 is positioned close to the gas distribution plate 64 to facilitate the plasma CVD deposition on the surface of the substrate 240. Since the PECVD, or HDP CVD, deposition process uniformity and deposition rate are affected by the interaction of the substrate surface with the generated plasma, the processing position of the substrate support may be adjusted according to the process variables found in the plasma CVD processing recipe. The optimal plasma processing position is strongly dependent on the plasma processing chamber attributes (e.g., chamber size, substrate position relative to pumping ports, etc.) and the configuration of the RF energy transmitting device(s) relative to the substrate surface. In one embodiment the processing position may be varied as the plasma ion density is adjusted during the plasma processing steps.

In an effort to prevent arcing, plasma induced damage to chamber components, and/or minimize power loss and unwanted deposition of a dielectric material on the substrate support 238 and the chamber base 202, it may be necessary to minimize plasma generation or interaction with components in the lower volume 19. Typically plasma processing chambers are designed to prevent the plasma generation in unwanted areas of the chamber volume 17, but techniques commonly used are not applicable to chambers that allow relative motion between chamber components or ones that are used to process large area substrates (e.g., >2000 cm²). Large area substrates raise unique concerns created by large atmospheric pressure effects on components that are at an atmosphere/vacuum interface, increased chamber complexity due to RF grounding and thermal uniformity concerns caused by the size of the substrate, and/or the large component piece part cost of such large components. In an effort to resolve these issues, in one embodiment a physical barrier (not shown) that allows relative motion between the substrate support 238 and the chamber base 202 is installed to prevent or inhibit the plasma leakage or generation in the lower volume 19. The physical barrier, in this embodiment, can be attached to the chamber bottom 208 and a surface of the moveable substrate support 238. In one embodiment the physical barrier may be a conductive, preferably metal, bellows or a flexible conductive wire mesh or grid positioned so that it can prevent plasma from being generated. In another embodiment it may beneficial to shield individual components (not shown) in the lower volume 19 to minimize the deposition on or plasma interaction with these components. In another embodiment, the evacuation rate (e.g., pumping rate and conductance between the process volume 18 and the lower volume 19) of the vacuum pumping system 152 and/or the vacuum pumping system 150 are controlled to minimize the gas flow from the process volume 18 into the lower volume 19 to minimize the effects of the plasma bombardment and chemistry.

To remove any unwanted deposits from the surfaces in the plasma processing chamber 100 a cleaning gas from a cleaning source 120, which is coupled to the entry port 112, is used to remove the deposition on the components in the chamber volume 17. The cleaning source 120 typically provides a cleaning agent, such as disassociated fluorine, that is introduced into the chamber volume 17.

Cluster Tool Apparatus and Wafer Sequencing

Aspects of the present invention also provide a cluster tool 310 that contains at least one plasma processing chamber 100 that is capable of depositing a high quality gate dielectric layer. A cluster tool 310 is advantageous because it supports both the pre-processing steps, such as, preheating the substrate, pre-cleaning the surface of the substrate prior to processing, and post-processing steps, such as, post anneal and cool down, all in a single controlled environment. The use of a controlled environment to deposit a gate dielectric layer can be an important aspect of forming a high quality gate dielectric layer since exposure of the substrate surface to atmospheric contamination between the HDPO layer and dielectric layer deposition steps can lead to poor electrical properties of the formed gate layer, in cases where separate chambers or, worse, separate systems are used to deposit the HDPO layer and dielectric layer. Also, the incorporation of an anneal, a preclean and/or a preheat chamber (all discussed below) to the cluster tool will reduce generated defects in the formed gate dielectric layer 4 if these processes are completed without exposure to atmospheric contamination sources or these processes are completed just prior to or soon after performing the HDPO layer and/or dielectric layer deposition process(es).

FIG. 8 illustrates a representative cluster tool 310 that incorporates a plasma processing chamber 100. The cluster tool 310 represents a cluster tool that can be used to process substrates 240 without exposing the substrates to air. Cluster tool 310 comprises a central transfer chamber 312 to which are connected load lock/cooling chambers 314A and 314B, a preheat chamber 302, and processing chambers 340, 342, 344, and 346. The central transfer chamber 312, loadlock/cooling chambers 314A and 314B, preheat chamber 302, and processing chambers 340, 342, 344, and 346 are sealed together to form a closed environment in which the system is operated at internal pressures of about 10 mTorr to about 1 Torr. Load lock/cooling chambers 314A and 314B have closable openings comprising load doors 316A and 316B, respectively, to transfer the substrates 240 into cluster tool 310. The substrate 240 are transferred to either of the loadlock/cooling chambers 314A or 314B from one of the substrate storage positions 38A-D, by use of an atmospheric robot (not shown).

The loadlock/cooling chambers 314A and 314B each contain a cassette 317 fitted with a plurality of shelves for supporting and cooling substrates. Cassettes 317 in loadlock/cooling chambers 314 are mounted on an elevator assembly (not shown) to raise and lower the cassettes 317 incrementally by the height of one shelf. To load chamber 314A, load door 316A is opened and a substrate 240 is placed on a shelf in cassette 317 in loadlock/cooling chamber 314A. The elevator assembly then raises cassette 317 by the height of one shelf so that an empty shelf is opposite load door 316A. Another substrate is placed on the empty shelf and the process is repeated until all of the shelves of cassette 317 are filled. At that point, load door 316A is closed and loadlock/cooling chamber 314A is evacuated to the pressure in cluster tool 310.

A slit valve 320A on the inside wall of loadlock/cooling chamber 314A adjacent to central transfer chamber 312 is then opened. Substrates 240 are transferred by means of robot 322 in central transfer chamber 312 to a preheat chamber 302 where they are preheated to a desired temperature. In one embodiment, a substrate 240 is heated in the preheat chamber 302 to a temperature in the range of about 250° C. to about 450° C. In another embodiment, a substrate 240 is pre-heated in the load lock/cooling chamber 314 to a temperature in the range of about 250° C. to about 450° C., and thus a preheat chamber 302 is not needed to perform this function. The robot 322, which is controlled by the controller 300, is used to withdraw a substrate from cassette 317 of loadlock/cooling chamber 314A, insert the substrate onto an empty shelf in preheat chamber cassette 329 and withdraw, leaving the substrate on a shelf within preheat chamber 302. Typically, preheat chamber cassette 329 is mounted on an elevator assembly (not shown) within preheat chamber 302. After loading one shelf, preheat chamber cassette 329 is raised or lowered to present another empty shelf for access by robot 322. Robot 322 then retrieves another substrate from cassette 317 of loadlock/cooling chamber 314A.

In a like manner, robot 322 transfers all or a portion of substrates 240 from preheat chamber cassette 329 to one of four processing chambers 340, 342, 344 and 346. Each processing chamber 340, 342, 344 and 346 is optionally fitted on its inner walls 340A, 342A, 344A and 346A, respectively, with its associated slit valve 341, 343, 345 or 347, for isolation of the process gases. In one embodiment, processing chambers 340, 342, 344 and 346 are plasma processing chambers 100, as described above. The plasma processing chambers in this configuration are capable of forming a HDPO layer and a conventional PECVD deposition process of a high quality gate oxide layer, all in the same chamber. This embodiment will improve substrate throughput (e.g., substrates processed per hour) because the number of robot 322 handoffs between the HDPO and PECVD chambers in the cluster tool 310 will be greatly reduced. Also, this embodiment will allow many different types of process chambers and process chamber configurations to be attached to the cluster tool 310 to help resolve any possible process sequence bottlenecks. In another embodiment the HDPO process is completed in a first chamber mounted to the cluster tool system and then a second dielectric deposition step is completed in a second processing chamber mounted to the cluster tool system. In this embodiment, the first module (e.g., processing chamber 340) is configured to perform a HDPO process as described above and a second module (e.g., processing chamber 342) is configured as a HDP CVD or PECVD reactor to deposit a dielectric layer. In this embodiment, an HDPO layer is grown on substrate 240 before the dielectric layer is applied to substrate 240 in the subsequent module (e.g., processing chamber 342). In one embodiment, the substrate 240 is transferred from a first module (e.g., processing chamber 340) to the preheat chamber 302 prior to the substrate being processed in the subsequent module (e.g., processing chamber 342). The substrate is heated to a temperature of about 250° C. to about 450° C. in the preheat chamber before being processed in the subsequent module.

After the substrate 240 is processed in at least one of the processing chambers 340, 342, 344 or 346 the substrate is transferred to cassette 317 of the load lock/cooling chamber 314B. The substrate is cooled in the cool down chamber by use of a cooling surface which removes heat from the substrates mounted in the cassette 317. The cooling surface is cooled using a conventional heat exchanging fluid flowing through a heat exchanger mounted to the cooling surface. Once the substrates has reached a desired temperature, typically in a range between about 20 and about 150° C., the substrate is removed from the chamber 314B through an opened load door 316B and placed in one of the substrate storage positions 38A-D

In one embodiment of the cluster tool 310, the cluster tool 310 contains at least one preclean chamber mounted in one of the processing chambers 340, 342, 344, and 346 positions or the preheat chamber 329 position. The preclean chamber is added to the system to remove any unwanted material (e.g., surface oxides, contaminants, etc.) prior to depositing the gate dielectric layer 4. The preclean process is a plasma cleaning process, where oxides and other contaminants are removed from the surface of the substrate by use of a light sputter etch and/or by use of a plasma etching chemistry (e.g., NF₃, CF₃, etc.). The pre clean process is typically a non-selective RF plasma etching process completed using an inert gas (e.g., argon, xenon, kypton, etc.) and an inductively and/or capacitively coupled plasma driven at an RF frequency in a range between about 0.3 MHz and above 10 GHz. The RF power required to perform the preclean process is strongly dependent on the size of the chamber, the desired preclean etch rate, and the substrate bias voltage. The preclean process may be added to the cluster tool 310 processing sequence before or after the preheat step, but prior to the plasma processing step(s). In one embodiment the preheat and preclean processes are completed in the same chamber. In another embodiment, this preheat process is completed in the plasma processing chamber and the preclean step is completed prior to the preheat step. In another embodiment the preclean process may be performed in situ in the plasma processing chamber 100 prior to processing. In yet another embodiment the preclean and preheat processes may be performed in situ in the plasma processing chamber 100 prior to processing. Alternatively, in another embodiment, the substrate 240 can be cleaned prior to insertion into the cluster tool 310, by use of wet chemical clean such as an aqueous solution containing HF, NH₄OH/H₂O₂, HNO₃, or HCl, or a mild alkaline solution. The use of a preclean chamber in the controlled environment of a cluster tool can be an important aspect of forming a high quality gate oxide layer since exposing the p-Si source, drain and channel surfaces to atmospheric contamination after a preclean process has been completed but before the HDPO layer has been formed can also lead to poor electrical properties of the gate layer and thus defeat the purpose of the preclean process.

In one embodiment of the cluster tool 310, the cluster tool 310 contains at least one anneal chamber mounted in one of the processing chambers 340, 342, 344, and 346 positions or the preheat chamber 329 position. The anneal chamber is added to the system to reduce the number of defects created during the formation of the gate dielectric layer. The anneal process is a thermal process, where the substrate is processed in the anneal chamber for a desired period of time at temperatures in a range between about 400° C. and about 550° C. The annealing step may occur in an atmosphere containing nitrogen, an inert gas, or possibly a mixture of nitrogen and hydrogen, e.g., about 95% nitrogen and 5% hydrogen. The anneal process may also be performed in a vacuum. The annealing step may take about five to thirty minutes, e.g., about ten minutes. Due to the desire to increase throughput it may be desirable to provide two or more annealing chambers. After the annealing step is completed, the substrate 240 is transferred to one of the cooling/load lock chambers 314A-B to be cooled to a handling temperature. An exemplary method of performing an annealing process and an exemplary hardware configuration in a cluster tool is further described in the United States Patent Application U.S. Pat. No. 6,610,374, entitled “Method Of Annealing Large Area Glass Substrates”, filed on Sep. 10, 2001, which is incorporated by reference herein to the extent not inconsistent with the claimed aspects and disclosure herein. The use of a anneal chamber in the controlled environment of a cluster tool can be an important aspect of forming a high quality gate oxide layer since the implementation of an anneal step right after the gate dielectric layer formation processes can reduce any possible intrinsic or extrinsic stress induced damage to the gate dielectric layer.

While the foregoing is directed to embodiments of the present invention, other and further embodiments of the invention may be devised without departing from the basic scope thereof, and the scope thereof is determined by the claims that follow.

1. A chamber for plasma processing a substrate, comprising:
one or more chamber walls defining a plasma processing region;
a substrate support member mounted in the plasma processing region and adapted to support the substrate at a plurality of vertically spaced apart plasma processing positions;
a RF transmitting device positioned to transmit RF energy to the plasma processing region;
an RF power source connected to the RF transmitting device; and
an oxidizing gas source in communication with the plasma processing region.

2. The apparatus of claim 1, wherein the RF transmitting device is an inductively coupled RF energy transmitting device.

3. The apparatus of claim 1, wherein the RF transmitting device is a capacitively coupled RF energy transmitting device and the ratio of the surface area of a grounded surface in contact with the plasma processing region to the surface area of the RF transmitting device in contact with the plasma processing region is between about 1:1 to about 2:1.

4. The apparatus of claim 1, further comprising:
a controller that is connected to the RF power source and the gas source, wherein the controller is adapted to control the RF energy delivered to the RF transmitting device and the gases delivered to the plasma processing region from the oxidizing gas source.

5. The apparatus of claim 4, further comprising:
a memory, coupled to the controller, the memory comprising a computer-readable medium having a computer-readable program embodied therein for directing the operation of the plasma processing chamber, the computer-readable program comprising:
computer instructions to control the plasma processing chamber to:
(i) start processing;
(ii) move the substrate support member to a first plasma processing position;
(iii) process the substrate at a first RF power using a first gas delivered from the gas source;
(iv) stop plasma processing after a user defined time;
(v) move the substrate support member to a second plasma processing position;
(vi) process the substrate at a second RF power using a second gas delivered from the gas source; and
(vii) stop plasma processing after a user defined time.

6. A chamber for plasma processing a substrate, comprising:
one or more chamber walls defining a plasma processing region;
a substrate support member mounted in the plasma processing region and adapted to support the substrate at a plurality of vertically spaced apart plasma processing positions;
a first RF transmitting device positioned to transmit RF energy to the plasma processing region;
a first RF power source connected to the first RF transmitting device;
a second RF transmitting device positioned to transmit RF energy to the plasma processing region;
a second RF power source connected to the second RF transmitting device;
an oxidizing gas source in communication with the plasma processing region; and
a controller that is connected to the first RF power source, the second RF power source, and the gas source, wherein the controller is adapted to control the RF energy delivered to the first RF transmitting device, the RF energy delivered to the second RF transmitting device, and the gases delivered to the plasma processing region from the oxidizing gas source.

7. The apparatus of claim 6, further comprising
a third RF transmitting device positioned to transmit RF energy to the plasma processing region;
a third RF power source connected to the third RF transmitting device; and
wherein said controller is connected to the first RF power source, the second RF power source, the third RF power source, and the gas source, wherein the controller is adapted to control the RF energy delivered to the first RF transmitting device, the RF energy delivered to the second RF transmitting device, the RF energy delivered to the third RF transmitting device, and the gases delivered to the plasma processing region from the oxidizing gas source.

8. The apparatus of claim 7, wherein the first RF transmitting device is an RF coil, the second RF transmitting device is a gas distribution plate, and the third RF transmitting device is a substrate support.

9. A method of forming an gate dielectric layer on a substrate, comprising:
moving the substrate to a first of a plurality of processing positions in a plasma processing region of a plasma processing chamber;
flowing an oxidizing gas mixture into the plasma processing region;
generating a plasma in the plasma processing region at a substrate surface temperature of no more than about 550° C. to form an oxidized surface on the substrate;
moving the substrate to a second of the plurality of processing positions; and
forming a dielectric layer on the surface of the substrate to form a gate dielectric layer having a thickness from about 100 Å to about 6000 Å.

10. The method of claim 9, wherein the oxidized surface on the substrate has a thickness from about 20 Å to about 500 Å.

11. The method of claim 9, wherein the dielectric layer formed on the surface of the substrate is formed using a tetraethylorthosilicate.

12. The method of claim 9, wherein the oxidizing gas mixture contains a source of oxygen.

13. The method of claim 12, wherein the oxidizing gas mixture further comprises helium, hydrogen, argon, xeon, krypton or combinations thereof.

14. A method of forming a gate dielectric layer on a substrate, comprising:
moving the substrate to a first of a plurality of processing positions in a plasma processing region of a plasma processing chamber;
flowing an oxidizing gas mixture into the plasma processing region;
generating a plasma in the plasma processing region at a substrate surface temperature of no more than about 550° C. using a first RF transmitting device;
moving the substrate to a second of the plurality of processing positions in a plasma processing region of a plasma processing chamber;
flowing a dielectric layer forming gas mixture into the plasma processing region; and
generating a plasma in the plasma processing region at a substrate surface temperature of no more than about 550° C. using a second RF transmitting device to form a dielectric layer on the surface on the substrate.

15. The method of claim 14, wherein the first RF transmitting device is an inductively coupled RF transmitting device and the second RF transmitting device is a capacitively coupled RF transmitting device.

16. The method of claim 14, wherein the dielectric layer forming gas contains tetraethoxysilane or tetraethylorthosilicate.

17. The method of claim 14, wherein the oxidizing gas mixture contains a source of oxygen.

18. The method of claim 17, wherein the oxidizing gas mixture further comprises helium, hydrogen, argon, xeon, krypton or combinations thereof.

19. The method of claim 14, wherein generating a plasma in the plasma processing region using a first RF transmitting device further comprises generating a plasma in the plasma processing region using a second RF transmitting device.

20. The method of claim 14, wherein forming a dielectric layer is completed using a silicon, an oxygen and/or a nitrogen containing gas using an inductively coupled RF energy transmitting device and a capacitively coupled RF energy transmitting device.

21. The method of claim 20, wherein the capacitively coupled RF energy transmitting device is a gas distribution plate or a substrate support.

22. A cluster tool for forming a high quality gate oxide layer on a substrate, comprising:
a plurality of plasma processing chambers adapted for forming an oxidized surface on the substrate and depositing a dielectric layer on the substrate to form a gate dielectric layer; and
a controller configured to maintain the substrate at a temperature no more than about 550° C.

23. The cluster tool of claim 22, further comprising a second chamber adapted to preclean the substrate prior to forming the gate dielectric layer on the substrate.

24. The cluster tool of claim 22, further comprising a second chamber adapted to anneal the substrate at a temperature between about 60° C. to about 550° C. after forming the gate dielectric layer on the substrate.

25. The cluster tool of claim 22, further comprising a second chamber adapted to preheat the substrate to a temperature between about 60° C. to about 550° C. prior to forming the gate dielectric layer on the substrate.

26. The cluster tool of claim 22, wherein the plurality of plasma processing chambers are a plurality of high density plasma oxidation (HDPO) chambers, the HDPO chamber comprising:
one or more chamber walls defining a plasma processing region;
a substrate support member mounted in the plasma processing region and adapted to support the substrate at a plurality of vertically spaced apart plasma processing positions;
a RF transmitting device positioned to transmit RF energy to the plasma processing region;
an RF power source connected to the RF transmitting device; and
an oxidizing gas source in communication with the plasma processing region.

27. A cluster tool for forming a high quality gate oxide layer on a substrate, comprising:
a first chamber adapted to form an oxidized surface on a substrate at a temperature no more than about 550° C.; and
a second chamber adapted to deposit a dielectric layer onto the oxidized surface on the substrate at a temperature no more than about 550. ° C.

28. The cluster tool of claim 27, further comprising a third chamber adapted to preheat the substrate to a temperature between about 60° C. to about 550° C. prior to forming an oxidized surface on the substrate.

29. The cluster tool of claim 27, wherein the first chamber is a high density plasma oxidation (HDPO) chamber, the HDPO chamber comprising:
one or more chamber walls defining a plasma processing region;
a substrate support member mounted in the plasma processing region and adapted to support the substrate at a plurality of vertically spaced apart plasma processing positions;
a RF transmitting device positioned to transmit RF energy to the plasma processing region;
an RF power source connected to the RF transmitting device; and
an oxidizing gas source in communication with the plasma processing region.

30. The cluster tool of claim 27, wherein said second chamber is a plasma chemical vapor deposition chamber, the second chamber comprising:
one or more chamber walls defining a plasma processing region;
a substrate support member mounted in the plasma processing region, adapted to support the substrate;
an RF transmitting device positioned to transmit RF energy to the plasma processing region;
an RF power source connected to the RF transmitting device; and
a gas source in communication with the plasma processing region.

31. The cluster tool of claim 27, further comprising a third chamber adapted to preclean the substrate prior to processing in the first chamber.

32. The cluster tool of claim 27, further comprising a third chamber adapted to anneal the substrate at a temperature between about 60° C. to about 550° C. after forming the gate dielectric layer on the substrate.

33. A chamber for plasma processing a substrate, comprising:
one or more chamber walls defining a plasma processing region;
a substrate support member mounted in the plasma processing region and adapted to support the substrate at a plurality of vertically spaced apart plasma processing positions;
an RF coil positioned to transmit RF energy to the plasma processing region;
an RF power source connected to the RF coil;
a gas distribution plate positioned to transmit RF energy to the plasma processing region;
an RF power source connected to the gas distribution plate; and
an oxidizing gas source in communication with the plasma processing region.

34. The apparatus of claim 33, wherein the RF coil is a single turn coil.

35. The apparatus of claim 33, further comprising a cover which is adjacent to the RF coil so that the cover can shield the RF coil from a plasma generated in the plasma processing region.

36. A chamber for plasma processing a substrate, comprising:
one or more chamber walls defining a plasma processing region;
a substrate support member mounted in the plasma processing region and adapted to support the substrate at a plurality of vertically spaced apart plasma processing positions, wherein the substrate support is positioned to transmit RF energy from an RF power source to the plasma processing region;
a gas distribution plate mounted in the plasma processing region, wherein the gas distribution plate is grounded; and
an oxidizing gas source in communication with the plasma processing region.

37. The apparatus of claim 36, wherein the ratio of the surface area of a grounded surface in contact with the plasma processing region to the surface area of the substrate support surface area is between about 1:1 and about 2:1.
